(19) United States
(12) Patent Application Publication
(10) Pub. No.: US 2026/0349042 A1
(43) Pub. Date: Nov. 5, 2026

(54) SYSTEMS AND METHODS FOR DETECTING OPEN BATTERY CONDITION IN DC POWER SYSTEM

(71) Applicant: Hindle Power, Inc., Easton, PA (US)

(72) Inventors: Robert D. Beck, Allentown, PA (US); Chris Fritchman, Zionsville, PA (US); David Skok, Allentown, PA (US); Philip Dunmire, Bethlehem, PA (US); Nicholas C. Hindle, Easton, PA (US)

(73) Assignee: Hindle Power, Inc., Easton, PA (US)

(21) Appl. No.: 19/482,348

(22) PCT Filed: May 8, 2024
(86) PCT No.: PCT/IB2024/054503

§ 371 Date: Nov. 7, 2025

Related U.S. Application Data
(60) Provisional application No. 63/465,009, filed on May 9, 2023.
(60) Provisional application No. 63/541,976, filed on Oct. 2, 2023.

(51) Int. Cl. G01R 31/3842; G01R 31/36; G01R 31/374

(52) U.S. Cl. CPC G01R 31/3842; G01R 31/3646; G01R 31/374

(57) ABSTRACT

Continuous monitoring for an open battery condition is provided. Systems and methods are provided that determine when a battery has been disconnected from a direct current (DC) system, as well as a method of determining and displaying remaining amp-hour capacity of the battery. Embodiments described herein provide constant monitoring of battery continuity, e.g., in a DC subsystem of a utility substation.

### BACKGROUND

A commercial electrical substation (e.g., a utility substation) comprises various components including a battery charger, a battery, and a distribution system. A utility that operates the substation seeks to minimize the maintenance required to keep these systems working.

Direct current (DC) systems of a power utility often include DC relay systems located at a power utility substation. Such DC relay systems often include a backup service battery system. Such a backup service battery system is often, but not necessarily, a stationary system having a battery charger that maintains the battery fully charged and supplies power to the DC load under normal operation. In the event that supply power is lost to the battery charger, the backup service system switches to battery power to supply uninterrupted power to the DC load. Thus, the DC relays at a power substation might maintain power to provide power switching in the event of an emergency condition, such as a blackout or brownout.

The utility does not always know the state of their battery or if their battery will perform as expected. The utility also does not know whether the battery is connected to the DC system. A breaker or battery disconnect may have been left open (e.g., the battery charger is not connected to the battery), or the battery may have been stolen, for example. Detecting the battery is disconnected is difficult because the battery charger normally powers the system load. In addition, there may be multiple chargers connected to the bus, each which may be supplying the system load. There are many conventional approaches to battery health prediction, some of which can detect but not confirm an open battery. However, these approaches are complex and often unreliable.

It is with respect to these and other considerations that the various aspects and embodiments of the present disclosure are presented.

### SUMMARY

Systems and methods are provided that continuously detect an open battery condition. Systems and methods are provided that determine when a battery has been disconnected from a DC system.

This summary is provided to introduce a selection of concepts in a simplified form that are further described below in the detailed description. This summary is not intended to identify key features or essential features of the claimed subject matter, nor is it intended to be used to limit the scope of the claimed subject matter.

### BRIEF DESCRIPTION OF THE DRAWINGS

The foregoing summary, as well as the following detailed description of illustrative embodiments, is better understood when read in conjunction with the appended drawings. Other aspects, features, and advantages of described embodiments will become more fully apparent from the following detailed description, the appended claims, and the accompanying drawings in which like reference numerals identify similar or identical elements. For the purpose of illustrating the embodiments, there is shown in the drawings example constructions of the embodiments; however, the embodiments are not limited to the specific methods and instrumentalities disclosed. In the drawings:

FIG. 1 shows a block diagram of an exemplary environment for detecting an open battery condition in accordance with described embodiments;

FIG. 2 shows a schematic representation of the environment of FIG. 1 with additional detail;

FIG. 3 shows a physical representation of the environment of FIG. 1 with additional detail;

FIG. 4 is an operational flow of an implementation of a method for detecting an open battery condition in accordance with described embodiments; and

FIG. 5 is an operational flow of a method for detecting an open battery condition in accordance with described embodiments.

### DETAILED DESCRIPTION

The ensuing detailed description provides example embodiments only, and is not intended to limit the scope, applicability, or configuration of the claims. Rather, the ensuing detailed description provides those skilled in the art with an enabling description for implementing the described embodiments. Various changes might be made in the function and arrangement of described elements without departing from the spirit and scope of the appended claims.

Directional terms may be used in this specification and claims to describe portions of the present invention (e.g., upper, lower, left, right, etc.). These directional terms are merely intended to assist in describing the embodiments, and are not intended to limit the scope of the claims. In addition, reference numerals that are introduced in the specification in association with a drawing figure may be repeated in one or more subsequent figures without additional description in the specification in order to provide context for other features.

Reference herein to “one embodiment” or “an embodiment” means that a particular feature, structure, or characteristic described in connection with the embodiment can be included in at least one embodiment. The appearances of the phrase “in one embodiment” in various places in the specification are not necessarily all referring to the same embodiment, nor are separate or alternative embodiments necessarily mutually exclusive of other embodiments. The same applies to the term “implementation.”

As used in this application, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion.

One or more aspects of the embodiments may be implemented as processing blocks in a software program, including possible implementation as a digital signal processor, micro-controller, or general-purpose computer; however, described embodiments are not so limited. As would be apparent to one skilled in the art, various functions of software might also be implemented as processes of circuits. Such circuits might be employed in, for example, a single integrated circuit, a multi-chip module, a single card, or a multi-card circuit pack.

Described embodiments might also be embodied in the form of methods and apparatuses for practicing those methods. Described embodiments might also be embodied in the form of program code embodied in non-transitory tangible media, such as magnetic recording media, optical recording media, solid state memory, floppy diskettes, CD-ROMs, hard drives, or any other non-transitory machine-readable storage medium, wherein, when the program code is loaded into and executed by a machine, such as a computer, the machine becomes an apparatus for practicing described embodiments. Described embodiments might also be embodied in the form of program code, for example, whether stored in a non-transitory machine-readable storage medium, loaded into and/or executed by a machine, or transmitted over some transmission medium or carrier, such as over electrical wiring or cabling, through fiber optics, or via electromagnetic radiation, wherein, when the program code is loaded into and executed by a machine, such as a computer, the machine becomes an apparatus for practicing the described embodiments. When implemented on a general-purpose processor, the program code segments combine with the processor to provide a unique device that operates analogously to specific logic circuits. Described embodiments might also be embodied in the form of a bitstream or other sequence of signal values electrically or optically transmitted through a medium, stored magnetic-field variations in a magnetic recording medium, etc., generated using a method and/or an apparatus of the described embodiments.

It should be understood that the steps of the methods set forth herein are not necessarily required to be performed in the order described, and the order of the steps of such methods should be understood to be presented as examples. Likewise, additional steps might be included in such methods, and certain steps might be omitted or combined, in methods consistent with various described embodiments.

As used herein in reference to an element and a standard, the term “compatible” means that the element communicates with other elements in a manner wholly or partially specified by the standard, and would be recognized by other elements as sufficiently capable of communicating with the other elements in the manner specified by the standard. The compatible element does not need to operate internally in a manner specified by the standard. Unless explicitly stated otherwise, each numerical value and range should be interpreted as being approximate as if the word “about” or “approximately” preceded the value of the value or range.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements. Signals and corresponding nodes or ports might be referred to by the same name and are interchangeable for purposes here.

Embodiments described herein provide a constant monitoring of battery continuity, e.g., in a direct current (DC) subsystem of a utility substation. Additionally or alternatively, remaining amp-hour capacity may also be determined and provided. As used herein, the term “remaining amp-hour capacity” is intended to mean the actual capacity of a battery relative to its rated capacity. Rated capacity is typically specified by the battery manufacturer. Remaining amp-hour capacity is typically represented as a percentage of the rated capacity. This differs from the common practice of providing amp-hours removed. In this manner, for example, a utility company has a straightforward technique of knowing current battery capacity and therefore helping the utility company determine a course of action such as battery replacement or capacity test. This increases reliability as it provides a stated indication of battery amp-hours. This helps maintenance as an indicator (e.g., a green light/red light) may be used to let the operator know the status of their battery.

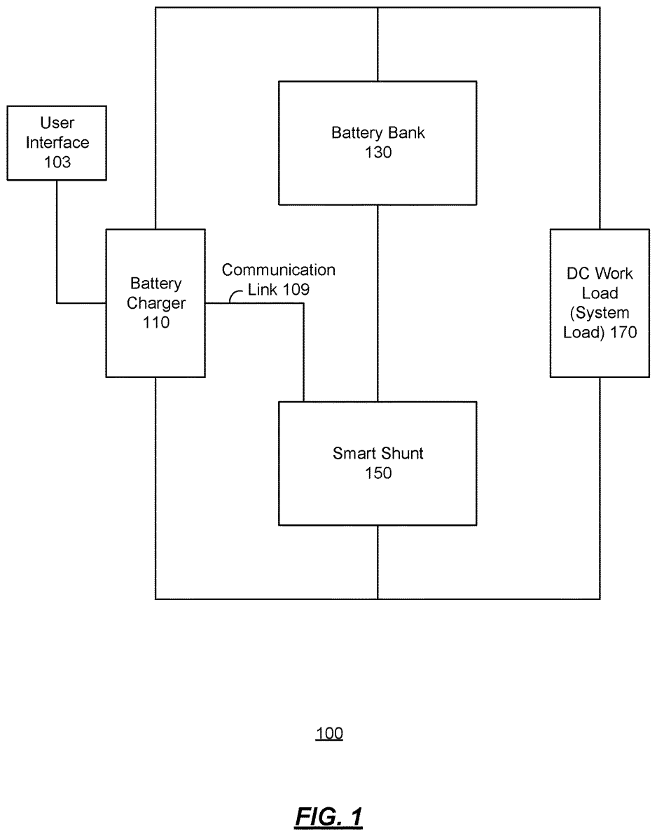

FIG. 1 shows a block diagram of an exemplary environment 100 for detecting an open battery condition in accordance with described embodiments. The environment 100 comprises a battery charger 110, a battery bank 130, a smart shunt 150, and a DC work load (i.e., a system load) 170. The environment 100 may be installed at a power substation in one or more physical enclosures, for example. A user interface 103 may typically include input/output devices such as an LCD screen, a touchscreen, a keyboard, push buttons, selector switches, or other similar user interface devices. The user interface 103 may be located with the one or more enclosures, and can be accessed by a technician, operator, or other user evaluating the status of, or changing the settings of, the environment 100, including the battery charger 110, the battery bank 130, and the smart shunt 150.

The term “open battery condition” as used herein means that when any current provided by a battery charger, such as the battery charger 110, is disconnected or otherwise discontinued, the battery bank, such as the battery bank 130, will not provide (i.e., is incapable of supplying) current to the load, such as the DC work load (i.e., the system load) 170. An open battery condition can be caused by a number of electrical faults, including a battery failure or an open circuit.

In some implementations, the battery charger 110 may be an AT battery charger or an ATEVO battery charger by Hindle Power, Easton PA, that receives alternating current (AC) input voltage and outputs DC voltage. The battery charger 110 is in communication with the smart shunt 150 via a communication link 109.

The battery bank 130 is monitored by the battery charger 110 or the smart shunt 150, and an alert or other indication is provided to the charger or a user based on the condition of the battery bank 130. For example, an alarm condition may be indicated (e.g., visually, by a red light) when the monitoring confirms an open battery condition. The battery bank 130 may comprise one or more batteries (connected in series, in parallel, or in other combination depending on the implementation), such as lead acid batteries and NiCad batteries, for example, although this is not intended to be limiting as many other types of batteries and arrangement of batteries may be used with the embodiments described herein.

It is contemplated that the smart shunt 150 may be implemented as an accessory to the battery charger 110, and may be configured to continuously provide open battery monitoring and remaining amp-hour capacity of the battery bank 130. In some implementations, the smart shunt 150 and the battery charger 110 together determine the capacity of the battery bank 130 and an open battery condition. More particularly, as described further herein, the smart shunt 150 may comprise an electronically enhanced shunt configured to calculate remaining amp-hour capacity and continuously detect an open battery condition in the battery bank 130. It is desirable to arrange the smart shunt 150 as close to the battery bank 130 as possible to maintain low impedance. It is contemplated that low impedance circuitry is implemented in the embodiments herein, which enables more accurate measurements of electrical parameters.

A decrease or the absence of float current may indicate an open battery condition. When the smart shunt 150 detects a reduction in float current of the battery bank 130, the smart shunt 150 triggers an open battery confirmation test to confirm whether an open battery condition truly exists. Once a low or no float current condition has been detected, the battery charger 110 performs the open battery test based on the data from the smart shunt 150 to confirm whether a battery is connected to the system. This confirmation step tests the ability of the battery bank 130 to supply the DC current required by the system load 170. Both steps require accurately measuring the DC system current(s), the DC system voltage, and temperature. These measurements are processed by an algorithm that determines whether a battery is connected to the DC system. In an embodiment, the open battery test comprises lowering the float voltage below a predetermined level (also referred to as a test voltage) for a predetermined amount of time to verify the battery has continuity and can support the load. In another embodiment, the open battery test raises the float voltage above a predetermined level for a predetermined amount of time and checks the current flowing into the battery; when the current flowing into the battery begins or increases, it may be verified that the battery has continuity and can support the load.

The environment 100 is configured such that the system load and battery load are common at the battery charger 110 but that the battery shunt is only able to measure the battery load. In this configuration, the battery shunt continuously measures the current passing through the battery bank 130.

The smart shunt 150 monitors the current in reference to a low current threshold, which is adjustable based on battery capacity. If the measurement dips below the low current threshold for a set period of time, the battery charger 110 initiates an open battery test based on data from the smart shunt 150. In an embodiment, the open battery test may reduce the float voltage below a low voltage alarm setpoint value for a set period of time to verify the battery can support the load, thus providing battery continuity. In another embodiment, the open battery test raises the float voltage and verifies that the current flowing into the battery starts or increases. The desired test voltage (either a reduction or increase) applied during the open battery test and the desired period of time the test voltage is applied will depend upon many factors, including but not limited to battery capacity, typical variations in float voltage, the nature of the load being carried by the system.

A benefit of this method is that battery continuity is tested in response to real-time conditions, rather than simply being performed on a predetermined schedule. Thus, when an open battery condition is suspected (based on a decrease or absence of float current), the open battery test is performed to determine if there is an open battery condition. Thus, the smart shunt 150 continuously monitors the DC system for an open battery condition, using a two-step process and without initiating a battery load test run by the charger (which would result in a discharge of the battery bank 130). This method eliminates false alarms that may be triggered during normal DC system operations when a one-step detection method is applied. It also eliminates the need to periodically initiate a battery discharge test to determine whether an open battery condition exists. Another benefit of raising the voltage during the open battery test is that this test will work when there are additional sources (battery chargers, batteries, power supplies, etc.) connected to the bus. Multiple chargers on the bus are common, and this open battery test can be used when the battery current is measured via the smart shunt 150. This also eliminates any discharge of the battery bank 130 that may be caused by other open battery tests. In the case of an open battery test in which the float voltage is reduced, a micro-discharge of the battery bank 130 may occur, but the discharge is so small that it would be very difficult to measure.

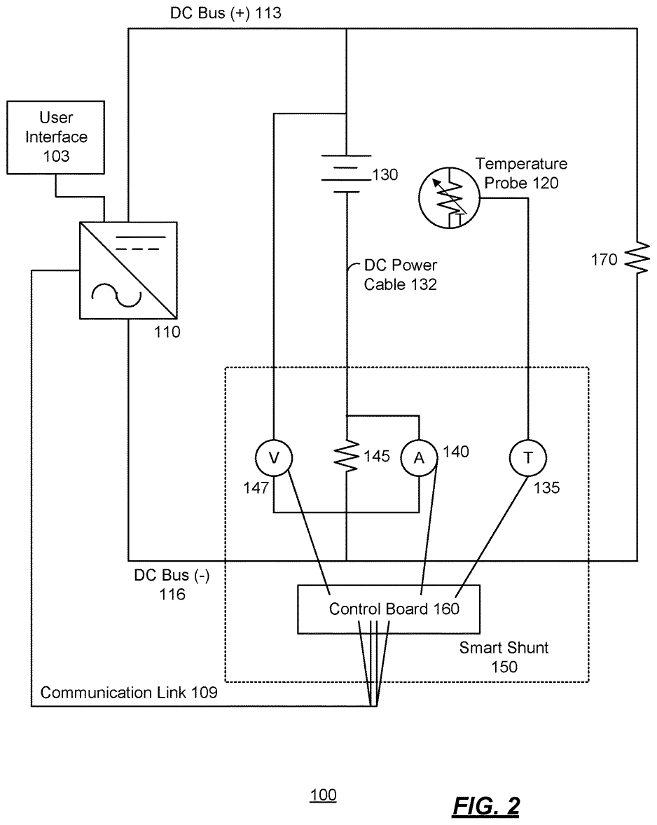

FIG. 2 shows a schematic representation of the environment 100 of FIG. 1 with additional detail. The smart shunt 150 comprises a temperature probe 120 with temperature measurement module 135, a current measurement module 140 including a measurement load 145 (e.g., a shunt in some implementations), a voltage measurement module 147, and a control board 160. The modules 135, 140, 147 are used to measure temperature of one or more of the batteries of the battery bank 130, as well as the current and voltage, respectively, which are used in subsequent calculations and determinations. A DC power cable 132 connects the battery bank 130 and the smart shunt 150.

The control board 160 is in communication with the battery charger 110 via the communication link 109. The communication link 109 might be wired or wireless. The battery charger 110 is connected to the DC work load 170 via a DC bus (+) 113 and a DC bus (−) 116. Similarly, the battery charger 110 is connected to the battery bank 130 and the smart shunt 150 via the DC bus (+) 113 and a DC bus (−) 116. Some connections between the various components may be wired or wireless, depending on the implementation, and it is noted that DC bus connections are wired.

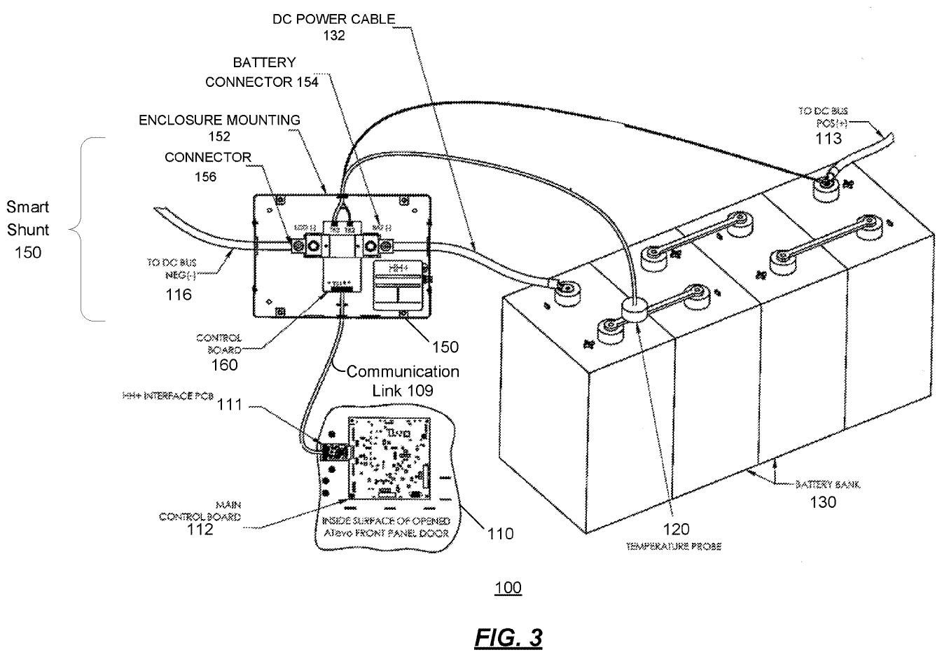

FIG. 3 shows a physical representation of the environment 100 of FIG. 1 with additional detail. The battery bank 130 is provided along with the DC bus (+) 113 and the DC bus (−) 116. As shown in the environment 100, the DC bus (+) 113 and the DC bus (−) 116 are placed across the battery bank 130. The temperature probe 120 is provided to measure the temperature of the battery bank 130, although this is not intended to be limiting as the temperature probe 120 can be configured to measure the temperature of any number of cells depending on the implementation.

A main control board 112 of the battery charger 110, such as an ATEVO™ battery charger, includes an interface printed circuit board (PCB) 111 to the control board 160 of the smart shunt 150. The smart shunt 150 includes a connector 156 to the DC bus (−) 116, and a battery connector 154 to the battery bank 130. An enclosure mounting 152 is also provided around the smart shunt 150. The DC power cable 132 is provided to connect the smart shunt 150 to the battery bank 130.

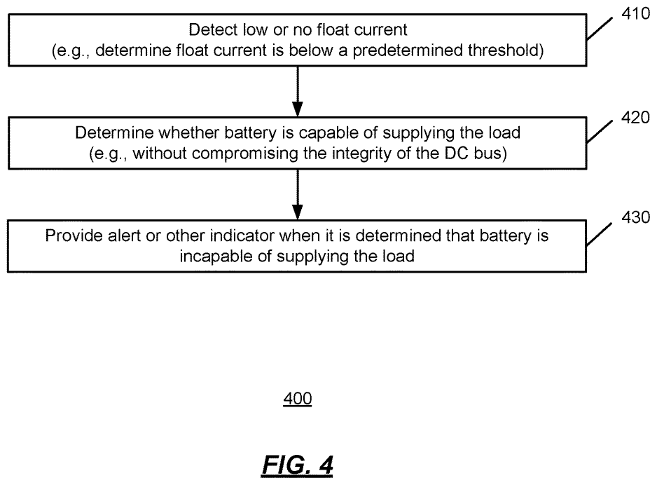

FIG. 4 is an operational flow of an implementation of a method 400 for continuously detecting an open battery condition in accordance with described embodiments. The method 400 may be performed in the environment 100 in some implementations.

At 410, a low float current or a no float current condition of the battery (or the battery bank 130) is detected. In an implementation, it is determined that the float current of the battery is below a predetermined threshold. Any known technique for determining the float current of a battery may be used. The threshold may be set or fixed/predetermined, and can be changed by a user (e.g., a technician, an operator, etc.), for example. In some implementations, the threshold may be dynamically or automatically set by the battery charger 110 or other computing device associated with the battery charger 110. This determination of a low float current or a no float current condition of the battery at 410 triggers an open battery test performed at 420.

At 420, the open battery test is performed and it is determined whether the battery is capable of supplying the load (e.g., the DC work load or system load, such as the load 170) without compromising the integrity of the DC bus. This determination may be made by verifying the battery will supply the load requirements, using any known technique. In some implementations, the technique confirms an open battery condition without discharging the battery. The open battery test step 420 comprises the test described further herein.

Regarding the open battery test, in a first embodiment, the open battery test reduces the float voltage below a low voltage alarm setpoint value for a set period of time to verify the battery can support the load, and in a second embodiment the float voltage is raised above a predetermined level for a predetermined amount of time, and this is used to verify whether or not the battery has continuity and can supply the load. In the second embodiment, the open battery condition will be detected when multiple sources are connected to the DC bus and all sources are capable of supplying the system load. The sources could be, but are not limited to, additional battery chargers, and/or additional battery strings. No additional control or wiring is required between the additional sources.

At 430, an alert or other indicator is provided when it is determined that the battery is incapable of supplying the load. The alert or indicator may be provided to a user (e.g., a technician, an operator, etc.) via a user interface, for example, such as the user interface 103.

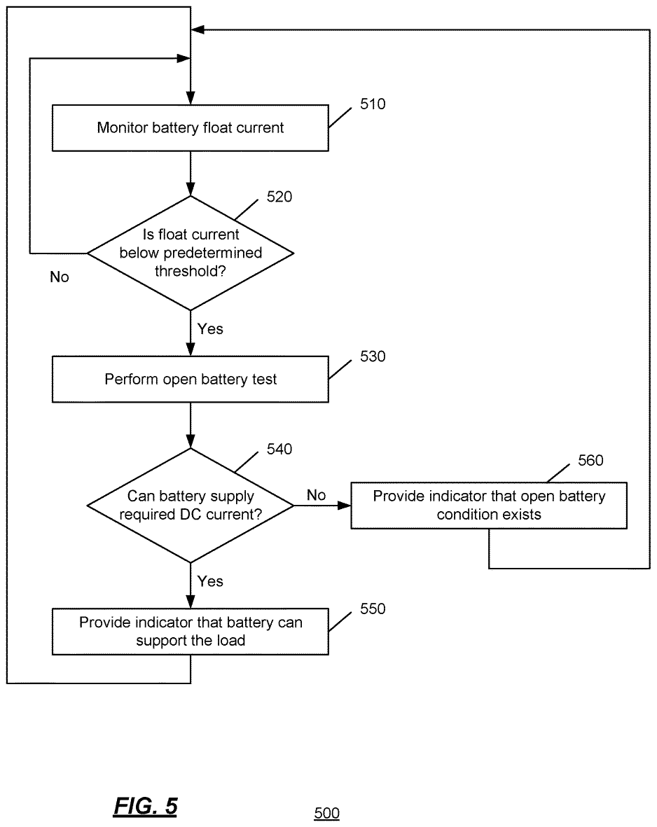

FIG. 5 is an operational flow of another implementation of a method 500 for continuously detecting an open battery condition in accordance with described embodiments. The method 500 may performed in any of the environments 100, 200, 300 in some implementations.

At 510, the battery float current is continuously (i.e., constantly) monitored. Similar to 410, any known technique for determining the float current of a battery may be used.

At 520, it is determined whether the float current is below a set or fixed/predetermined threshold that can be changed by a user (e.g., a technician, an operator, etc.), for example, though in some implementations, the threshold may be dynamically or automatically set by the battery charger 110 or other computing device associated with the battery charger 110. When the float current is not below (e.g., is equal to or exceeds) the predetermined threshold, then it is determined that a low float current or a no float current condition of the battery does not exist and monitoring continues in this mode at 510.

When at 520 it is determined that the float current is below the predetermined threshold, then an open battery test of the battery is performed at 530. In some implementations, performing the open battery test comprises confirming an open battery condition without discharging the battery. As described further herein, depending on the embodiment, the open battery test may apply a test voltage that is lower (or higher) than the float voltage for a predetermined amount of time based on battery capacity, and may be used to verify whether or not the battery has continuity and can supply the load.

Regarding the embodiment in which the test voltage is higher than the float voltage, the presence of an open battery condition can be determined by monitoring the current through the battery bank 130 when the test voltage is applied. The higher voltage will cause a micro-charge event in the battery bank 130. A change in current at the battery bank 130 will confirm that the battery bank is not in an open state, i.e., it will pass the open battery test. In some embodiments, a positive open battery test may require that the change in current at the battery bank 130 vs. the float current be proportional to the difference in voltage between the test voltage and the float voltage. In other words the battery bank 130 is determined to be present if the ratio of float current to test current is substantially equal to the ratio of the float voltage to test voltage.

Detecting a change in battery current can be accomplished using the smart shunt 150. Applying a test voltage that is higher than the float voltage will increase current at the charger 110, but a smart shunt 150 is necessary to confirm that the extra current is flowing through the battery bank. No other source can affect this open battery test because they will have a lower voltage output and therefore cannot drive current to the battery bank 130.

At 540, using the open battery test, it is determined whether the battery can supply the required DC current for the load (e.g., the DC work load or system load, such as the load 170). When it is determined at 540 that the battery can supply the required DC current for the load, then an indicator is provided at 550 to indicate the battery can support the load. The indicator may comprise for example a message and/or a green light being illuminated on a user interface, such as the user interface 103. At this point, the system qualified the battery is present, and it may remain in this mode until the low float voltage state returns to normal. After the float voltage returns to normal, processing continues at 510.

When it is determined at 540 that the battery cannot supply the required DC current for the load, then an indicator is provided at 560 to indicate that an open battery condition exists. The indicator may comprise for example a message and/or a red light being illuminated on a user interface, such as the user interface 103. The system will remain in this mode until the open battery state returns to normal. Processing then continues at 510.

In some embodiments, an algorithm determines the battery's remaining amp-hour capacity. A battery's remaining amp-hour capacity is the actual performance of the battery compared to the stated manufactured performance, at ideal conditions (e.g., the battery will perform per the manufacturer's published discharge table when kept at 77 °F and near perfect maintenance).

The smart shunt 150 algorithm takes into account multiple parameters to produce an overall battery status. In some implementations, the smart shunt can provide a system operator with insight into battery health and reliability by providing clear indication of battery remaining amp-hour capacity. By incorporating a shunt with measuring technology, float current, battery current, ripple voltage, temperature, the number of discharge cycles, and the depth of discharge are accurately captured and may be used to provide battery remaining amp-hour capacity, continuous open battery monitoring, and thermal runaway alarming, depending on the implementation. Regarding battery remaining amp-hour capacity, by accurately measuring charging characteristics, battery performance, and temperature, the algorithm can estimate the available battery energy by displaying remaining amp-hour capacity to the operator. Regarding continuous open battery monitoring, using accurate measurements of float current, an alarm can be indicated on a loss of continuity the moment it occurs. Regarding thermal runaway alarming, the smart shunt ability to accurately measure float current may alarm on abnormally high float current, a key prerequisite for a thermal runaway event, although it is noted that thermal runaway is detected by monitoring float current (e.g., rising), battery temperature, and ambient temperature.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

It will be further understood that various changes in the details, materials, and arrangements of the parts that have been described and illustrated in order to explain the nature of the described embodiments might be made by those skilled in the art without departing from the scope expressed in the following claims.

What is claimed:

1. A method comprising:
(a) applying a float voltage to a battery bank comprising at least one battery;
(b) monitoring a float current of the battery bank while step (a) is being performed;
(c) detecting if the float current of the battery bank being monitored in step (b) falls below a predetermined float current threshold for a predetermined period of time;
(d) performing an open battery test that determines whether the battery bank is capable of supplying a load;
(e) performing the open battery test of step (d) only if the float current of the battery bank is detected as falling below the predetermined float current threshold for the predetermined period of time in step (c); and
(f) providing a first indication if the battery bank is determined to be incapable of supplying the load in step (d).

2. The method of claim 1, wherein the open battery test of step 1(d) is performed without discharging the battery bank.

3. The method of claim 1, wherein step (a) comprises continuously monitoring the float current of the battery bank.

4. The method of claim 1, further comprising:
(g) providing a second indication if the battery bank is determined to be capable of supplying the load, the second indication being different from the first indication.

5. The method of claim 1, wherein the open battery test of step (d) comprises applying a test voltage to the battery bank for a predetermined amount of time and determining that the battery bank is capable of supplying a load if test current flowing through the battery bank while the test voltage is applied is different from the float current, the test voltage being different from the float voltage.

6. The method of claim 1, wherein the open battery test of step (d) comprises applying a test voltage to the battery bank for a predetermined amount of time and determining that the battery bank is capable of supplying a load if the absolute value of a ratio between the float current and a test current flowing through the battery bank while the test voltage is applied is substantially equal to the ratio of float voltage to the test voltage.

7. The method of claim 5, wherein the test voltage is greater than the float voltage.

8. The method of claim 5, wherein the test voltage is less than the float voltage.

9. The method of claim 8, wherein the test voltage is equal to or less than a low voltage alarm setpoint value.

10. The method of claim 1, wherein the predetermined float current threshold is determined as a function of a capacity of the battery bank.

11. A method comprising:
(a) supplying a float voltage to a battery;
(b) sensing a float current flowing through the battery bank is below a predetermined float current threshold while step (a) is being performed;
(c) applying a test voltage to the battery bank if the float current sensed in step (b) is below the predetermined float current threshold, wherein the test voltage is different from the float voltage;
(d) sensing a test current flowing through the battery bank while step (c) is being performed; and
(e) providing a first indication of an open battery condition if the test current sensed in step (d) is below a predetermined test current threshold.

12. The method of claim 11, wherein the test voltage is less than the float voltage.

13. The method of claim 11, wherein the test voltage is greater than the float voltage.

14. The method of claim 11, wherein the test voltage is equal to or less than a low voltage alarm setpoint value.

15. The method of claim 11, wherein the predetermined float current threshold is determined as a function of a capacity of the battery bank.

16. The method of claim 11, further comprising:
(f) providing a second indication of a closed battery condition if the test current sensed in step (d) is equal to or above the predetermined test current threshold, wherein the second indication is different from the first indication.

17. A method of measuring and displaying a remaining amp-hour capacity of a battery bank comprising at least one battery, the method comprising:
providing a battery charger that is electrically connected to a battery bank and a load, the charger and battery bank being in parallel electrical connection with the load;
providing a smart shunt comprising a temperature measurement module having a temperature probe configured to measure a battery bank temperature, a current measurement module configured to measure current flowing through the battery bank, a voltage measurement module configured to measure voltage across the battery bank, and a control board;
monitoring float current, battery bank current, ripple voltage, battery bank temperature, number of discharge cycles of the battery bank, and depth of discharge of the battery bank using the smart shunt;
calculating a remaining amp-hour capacity of the battery bank based on data gathered from the monitoring step; and
supplying information representative of the remaining amp-hour capacity to a user.
